(19) United States
(12) Patent Application Publication
(10) Pub. No.: US 2006/0108663 A1
(43) Pub. Date: May 25, 2006

(54) Surface mount inductor with integrated componentry

(76) Inventors: Christopher J. Sanzo, Providence, RI (US); Chuan Ni, West Warwick, RI (US)

Correspondence Address: TEXAS INSTRUMENTS INCORPORATED, P O BOX 655474, M/S 3999, DALLAS, TX, 75265, US

(21) Appl. No.: 10/993,704

(22) Filed: Nov. 19, 2004

(51) Int. Cl. H01L 23/34

(52) U.S. Cl. 257/531; 257/724

(57) ABSTRACT

Disclosed are inductor systems with reduced volume for use in larger electronic circuits. Embodiments of the invention are disclosed for a surface mount inductor system that includes an inductor having a niche for receiving an IC component interposed between the inductor and PCB. Preferably, the assembly is encapsulated to form a complete inductor system. Also disclosed is an inductor system wherein the inductor has a niche for receiving an IC component wherein a separate mounting substrate is not required. Examples of the invention include a point load power supply.

### TECHNICAL FIELD

The invention relates to integrated circuits (ICs). More particularly, the invention relates to inductors having additional, integral, circuit components and methods for using the same.

### BACKGROUND OF THE INVENTION

Point of load power supplies are becoming increasingly smaller and power densities are being made ever higher. Often, exotic assembly and circuit techniques are required to reduce the size of power components. Meanwhile, the size of the control components is also getting smaller and smaller. Inductors are relatively large components, and therefore those skilled in the arts have frequently devoted attention to the reduction of inductor size.

Trade-offs exist, however, in the design and implementation of smaller inductors. Physically smaller inductors, for example, tend to have higher resistance and to have reduced efficiency compared to their larger counterparts. Smaller inductors are also less able to withstand the application of high current levels. One prior art approach has been to mount the desired circuit components side-by-side. Using this approach, the smallest practical size inductor for a given application is mounted on a substrate, such as a printed circuit board (PCB). Adjacent to the inductor, additional IC components, also of the smallest practical size, are attached to the PCB. Thus, the overall area of the system on the PCB consists of the area occupied by the inductor, plus the area occupied by the additional components, plus any additional “wasted” area required in the layout due to electrical or mechanical constraints, such as gaps between components.

Efforts have also been made in the arts to arrange inductors vertically with additional IC components in order to conserve board area. Depicted in FIG. 1 (prior art) for example, is a state of the art through-hole mounted system 10 shown in cross-section. In the system 10 an inductor 12 is shown mounted on a substrate 14, which is in turn affixed to a PCB 16 by means of pins 18. An IC component 20, such as a controller, is mounted between the inductor substrate 14 and the PCB 16. Standoff shoulders 22 are typically interposed between the PCB 16 and the inductor substrate 14 in order to provide clearance for the IC component 20. In this way, an inductor assembly 10 may be manufactured having a maximum width denoted by W, and a maximum height denoted H. The total area of the assembly 10 is approximately the area occupied by the inductor 12 from the perspective of the top surface 15 of the PCB 16, and approximately the area of the additional component 20 from the perspective of the bottom surface 17 of the PCB 16. In this way, wasted area may be reduced, and benefits may sometimes be obtained by distributing the total area used by the assembly 10 between the opposing surfaces 15, 17 of the PCB 16.

Another approach known in the arts for conserving area in implementing inductors and associated circuitry is illustrated in the cross-section view of FIG. 2 (prior art). A surface mount system 26 is shown with an inductor 12 mounted on the top surface 15 of a PCB 16. An IC component 20 is mounted to the opposing surface 17 of the PCB 16 using standard solder attachment techniques. As in the example of FIG. 1 (prior art), the overall area of the system 26 is distributed to the opposing sides 15, 17 of the PCB 16. Additionally, a reduction in height H may be realized by virtue of the use of a surface-mountable inductor, eliminating the need for mounting pins. Note, however, that the overall width W of the system 26 remains essentially unchanged, as does the area occupied by the inductor 12 and the IC components 20.

Despite efforts to reduce the area required to implement circuits requiring the use of inductors, there remains a need for improvements in reducing the board area and volume required for the effective use of inductors in IC circuitry.

### SUMMARY OF THE INVENTION

In carrying out the principles of the present invention, in accordance with preferred embodiments thereof, reduced-volume inductor systems are described.

According to one aspect of the invention, a surface mount coupled inductor system includes at least one core and at least one conductive winding encircling the core. The inductor thus formed has a niche for receiving an IC component. An IC component is interposed in the niche and the system is packaged in encapsulant surrounding the inductor and IC, forming a surface mount coupled inductor system.

According to another aspect of the invention, a surface mount coupled inductor system further includes a substrate to which an inductor is operably affixed with an IC component interposed in a niche between the inductor and the substrate. Encapsulant surrounds the substrate, inductor, and IC.

According to yet another aspect of the invention, a surface mount coupled inductor system has a plurality of inductors, each of the inductors having one or more niches and one or more IC components interposed therein.

According to another aspect of the invention, a surface mount inductor system includes a substrate configured for receiving an inductor. An inductor affixed to the substrate has a niche for receiving an IC component. An IC component is interposed in the niche, between the inductor and the substrate.

According to another aspect of the invention, a surface mount inductor system includes an inductor having a niche for receiving an IC component. An IC component is interposed in the niche, providing a system wherein a separate substrate is not included.

According to another aspect of the invention, a surface mount inductor system includes more than one niche, each with one or more IC component operably coupled therein.

According to another aspect of the invention, a surface mount inductor system is configured for a point load power supply.

According to another aspect of the invention, a surface mount inductor system uses an IC that includes controller circuitry.

According to still another aspect of the invention, a surface mount inductor system is provided in which the IC includes sensor circuitry.

The invention has numerous advantages including but not limited to providing methods and circuits offering improvements in efficiency, area and volume reduction, and reduced costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 (prior art) is a simplified cutaway side view of an example of a through-hole mounted inductor and additional integrated circuit component according to the prior art;

FIG. 2 (prior art) is a simplified cutaway side view of an example of a surface mount inductor and additional integrated circuit component according to the prior art;

FIG. 3 is a simplified cutaway side view of an example of a preferred embodiment of the invention;

FIG. 4 is a bottom view of the example of the preferred embodiment of the invention shown in FIG. 3;

FIG. 5 is a top view of the example of the invention shown in FIGS. 3 and 4;

FIG. 6 is a simplified cutaway side view of an example of an alternative preferred embodiment of the invention;

FIG. 7 is a bottom view of the example of the alternative preferred embodiment of the invention shown in FIG. 6; and

FIG. 8 is a top view of the example of the invention shown in FIGS. 6 and 7.

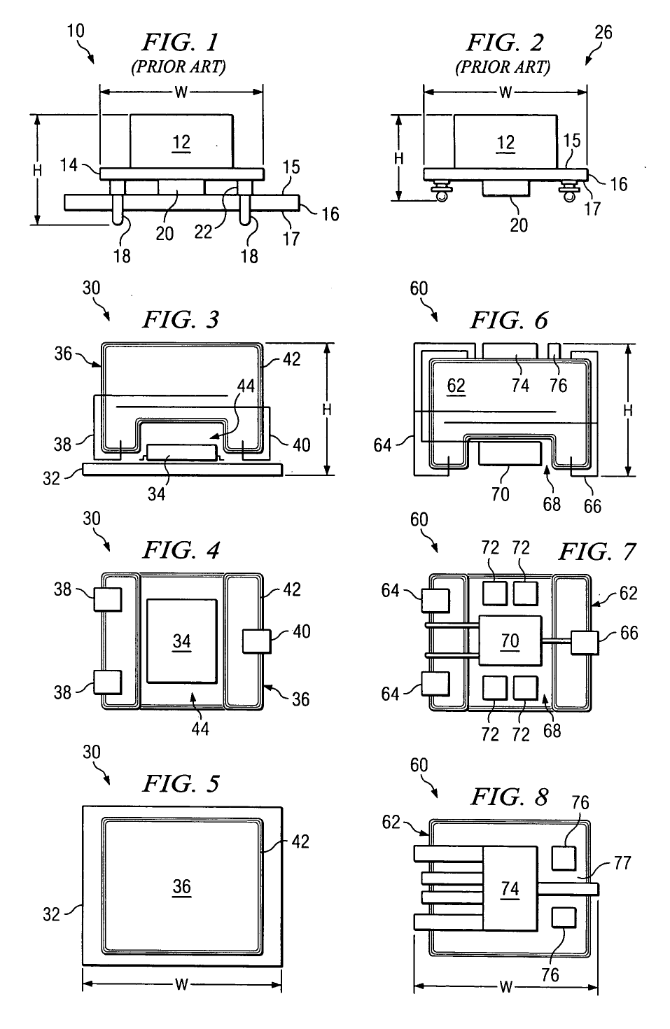

References in the detailed description correspond to like references in the various Figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides improved vertical integration of a circuit system that includes one or more conductive windings about a core of dielectric, ferromagnetic, or other suitable material, and one or more additional circuit components. As shown and described herein, preferred embodiments of the invention include a coupled inductor system configured to facilitate both vertical integration and a reduction in height.

Now referring primarily to FIG. 3, an example of a preferred embodiment of the invention is depicted in a partial cutaway side view. An inductor assembly 30 is shown with a PCB 32 providing a mounting surface for an IC 34. The IC 34 may be an individual component, such as a capacitor or transistor, or more complex microelectronic circuitry. The IC is preferably surface-mountable or unpackaged, although small packaged ICs, such as quad flat no-lead package (QFNs) may also be used. Typically, the IC 34 is selected for operation in association with the inductor 36. As known in the arts, the inductor 36, comprises terminals 38, an inductor shield 40, and a path of conductive material 42 selected to provide the desired electrical characteristics. According to the invention, the inductor 36 is also provided with a niche 44 configured to accept the placement of the IC 34 therein. The exact shape and size of the niche 44 is not crucial to the implementation of the invention so long as the niche 44 provides a volume of space adequate for placement of the IC 34. The embodiment of the invention shown in FIG. 3 is but one example of a suitable arrangement. Typically, the system 30 is packaged by encasing in encapsulant (not shown) with operable electrical connections familiar in the arts.

A bottom view of the system 30 (with the PCB and encapsulant absent) is shown in FIG. 4, wherein it may be observed that the outline of the IC 34 is wholly contained within the niche 44 of the inductor 42. The placement of the IC 34 within the footprint of the inductor 36 advantageously reduces the total PCB 32 surface area required for the system 30. In cases where the application may require a relatively large inductor and relatively small IC component, additional componentry, unrelated to the inductor in terms of circuit operation, may also be placed within the niche in order to reduce the overall area used by the application. FIG. 5 shows a top view of the system 30 (with encapsulant absent), in which it may be seen that the system 30 occupies an area approximately the same as that of the inductor 36, plus a small amount of clearance around the PCB 32.

An example of an alternative preferred embodiment of the invention is illustrated in FIG. 6. The inductor system 60 is an example of a point load power system supply. Shown in a partial cut-away side view, the inductor 62 has input/output terminals 64 and a ground terminal 66 for making electrical connections to associated circuitry (not shown). The inductor 62 has a niche 68 for receiving one or more additional IC components 70. The IC components 70 are preferably surface-mountable or unpackaged devices, although packaged ICs, such as QFNs may be used. In the present example, the IC 70 contains power control components for a point load power supply system 60. Now referring also to FIG. 7, it can be seen in this bottom view of the example of the invention also shown in FIG. 6 that additional components such as capacitors 72 may also be included in the niche 70, preferably to provide functionality for the system 60. For the purposes of this illustration, encapsulant typically used to package the system 60 is not shown.

As can be seen in FIG. 6 and the top view of FIG. 8, additional circuitry, such as the controller 74 shown in this example, and additional IC components, in this case, passive components 76 associated with the controller 74 may also be included on the top surface 77 of the inductor. Preferably, the configuration of the system is for a particular application with an eye toward achieving desirable height and width properties, H, W. Of course the description of the “top” and “bottom” surfaces herein are in reference to the drawings for the purposes of example. It should be appreciated by those skilled in the arts that in practice the niche could be on any side of the inductor, more than one side of the inductor, or each side of the inductor, without departure from the invention.

The invention provides advantages including but not limited to a reduction in the chip area and volume required for implementing an inductor and associated components, increased efficiency, and reduced costs. While the invention has been described with reference to certain illustrative embodiments, the methods and systems described are not intended to be construed in a limiting sense. Various modifications and combinations of the illustrative embodiments as well as other advantages and embodiments of the invention will be apparent to persons skilled in the art upon reference to the description and claims.

We claim:

1. A surface mount coupled inductor system comprising:
at least one core;
at least one conductive winding encircling each core, thereby forming at least one inductor, the inductor having a niche for receiving an IC component;
an IC component interposed in the niche; and
encapsulant surrounding the inductor and IC, forming a surface mount coupled inductor system for operably connecting to a circuit.

2. A surface mount coupled inductor system according to claim 1 wherein the system further comprises:
a substrate for receiving the inductor, wherein the inductor is operably affixed to the substrate, and wherein the IC component is interposed in the niche between the inductor and the substrate, and wherein the encapsulant surrounds the substrate, inductor, and IC.

3. A surface mount coupled inductor system according to claim 1 wherein the system further comprises a plurality of niches and a plurality of IC components interposed therein.

4. A surface mount coupled inductor system according to claim 1 wherein the system further comprises a plurality of inductors, each having one or more niches and one or more IC component interposed in one or more niche.

5. A surface mount coupled inductor system according to claim 1 wherein the system further comprises a power supply inductor.

6. A surface mount coupled inductor system according to claim 1 wherein the system further comprises a transformer.

7. A surface mount coupled inductor system comprising:
at least one core;
at least one conductive winding encircling each core, thereby forming at least one inductor, the inductor having a niche for receiving an IC component;
a substrate for receiving the inductor, wherein the inductor is operably affixed to the substrate;
an IC component interposed in the niche between the inductor and the substrate, the IC operably coupled to the substrate; and
encapsulant surrounding the substrate, inductor, and IC.

8. A surface mount coupled inductor system according to claim 7 wherein the system further comprises a plurality of niches and a plurality of IC components interposed therein.

9. A surface mount coupled inductor system according to claim 7 wherein the system further comprises a power supply inductor.

10. A surface mount coupled inductor system according to claim 7 wherein the system further comprises a transformer.

11. A surface mount inductor system comprising:
a substrate for receiving an inductor;
an inductor operably affixed to the substrate, the inductor having a niche for receiving an IC component; and
an IC component interposed in the niche between the inductor and the substrate, the IC operably coupled to the substrate.

12. A surface mount coupled inductor system according to claim 11 wherein the system further comprises encapsulant surrounding the substrate and inductor.

13. A surface mount inductor system according to claim 11 wherein the system further comprises a plurality of niches and a plurality of IC components interposed therein.

14. A surface mount inductor system according to claim 11 wherein the system further comprises a point load power supply.

15. A surface mount inductor system according to claim 11 wherein the IC further comprises controller circuitry.

16. A surface mount inductor system according to claim 11 wherein the IC further comprises sensor circuitry.

17. A surface mount inductor system comprising:
an inductor having a niche for receiving an IC component; and
an IC component interposed in the niche.

18. A surface mount coupled inductor system according to claim 17 wherein the system further comprises encapsulant surrounding the inductor and IC component.

19. A surface mount inductor system according to claim 17 wherein the IC is operably coupled to the inductor.

20. A surface mount inductor system according to claim 17 wherein the system further comprises a plurality of niches and a plurality of IC components interposed therein.
